(19) United States
(12) Patent Application Publication
(10) Pub. No.: US 2025/0028194 A1
(43) Pub. Date: Jan. 23, 2025

(54) SUBSTRATE WITH DIELECTRIC THIN FILM, OPTICAL WAVEGUIDE ELEMENT, AND OPTICAL MODULATION ELEMENT

(71) Applicant: TDK CORPORATION, Tokyo (JP)

(72) Inventors: Shusaku UMEMOTO, Tokyo (JP); Kenji SASAKI, Tokyo (JP); Takashi KIKUKAWA, Tokyo (JP)

(73) Assignee: TDK CORPORATION, Tokyo (JP)

(21) Appl. No.: 18/736,684

(22) Filed: Jun. 7, 2024

(30) Foreign Application Priority Data
Jul. 19, 2023 (JP) 2023-117245

(51) Int. Cl. G02F 1/035

(52) U.S. Cl. CPC G02F 1/035; G02F 2202/20; G02F 2202/42

(57) ABSTRACT

A substrate with a dielectric thin film 1 includes a single-crystal substrate, a stress relaxation layer, and a dielectric thin film, in which the stress relaxation layer is made of a c-axis-oriented epitaxial film, and includes a twin crystal structure of LiNbO₃ including a first and a second crystal existing at a position obtained by rotating the first crystal 180° about a c-axis and a LiNb₃O₈ phase, the dielectric thin film is made of a lithium niobate film which is a c-axis-oriented epitaxial film, has the twin crystal structure of LiNbO₃, has a film thickness of 0.5 μm to 2 μm, and has a maximum domain width greater than a maximum domain width of the stress relaxation layer, and a percentage of a film thickness of the stress relaxation layer to the film thickness of the dielectric thin film is 5% to 25%.

### BACKGROUND OF THE INVENTION

### Field of the Invention

The present invention relates to a substrate with a dielectric thin film, and an optical waveguide element and an optical modulation element using the same.

Priority is claimed on Japanese Patent Application No. 2023-117245 filed Jul. 19, 2023, the content of which is incorporated herein by reference.

### Description of Related Art

In the related art, as an optical waveguide element and an optical modulation element, elements using a lithium niobate film epitaxially grown on a substrate are known.

For example, Patent Document 1 describes a substrate with a dielectric thin film including a dielectric thin film made of a c-axis-oriented lithium niobate film epitaxially formed on a main surface of a single-crystal substrate. Patent Document 1 describes that the dielectric thin film has a twin crystal structure including a first crystal and a second crystal existing at a position obtained by rotating the first crystal 180° about a c-axis, and in pole measurement by an X-ray diffraction method, a ratio between a first diffraction intensity corresponding to the first crystal and a second diffraction intensity corresponding to the second crystal is equal to or greater than 0.5 and equal to or less than 2.0.

Patent Document 2 describes an optical modulator having a lithium niobate film that is an epitaxial film formed on a main surface of a single-crystal substrate and has a ridge-shaped portion. Patent Document 2 describes that a lithium niobate film is epitaxially grown on a silicon single-crystal substrate via an epitaxial buffer layer for promoting epitaxial growth. Patent Document 2 describes that ZrO₂ is preferred as the epitaxial buffer layer.

Patent Document 3 describes an optical element having a structure in which a ruthenium lower electrode, a lithium niobate thin film which is an electro-optical effect material hetero-epitaxially formed on the ruthenium lower electrode, and an upper electrode made of a metal material are laminated in order on a hexagonal crystal sapphire substrate having a composition of Al₂O₃.

### Patent Document

[Patent Document 1] PCT International Publication No. WO2018/016428
[Patent Document 2] Japanese Unexamined Patent Application, First Publication No. 2014-142411
[Patent Document 3] Japanese Unexamined Patent Application, First Publication No. 2003-15098

### SUMMARY OF THE INVENTION

An optical waveguide element and an optical modulation element using a substrate with a dielectric thin film including a lithium niobate film epitaxially grown on a substrate are excellent in productivity compared to an optical waveguide element and an optical modulation element using a lithium niobate single-crystal substrate. This is because, on the substrate with a dielectric thin film including the lithium niobate film epitaxially grown on the substrate, a lithium niobate film having a desired film thickness can be formed by adjusting deposition conditions. That is, in a case where the substrate with a dielectric thin film including the lithium niobate film epitaxially grown on the substrate is used, unlike a case where the lithium niobate single-crystal substrate is used, there is no need for adjusting the thickness by cutting or polishing the lithium niobate single-crystal substrate. In addition, the substrate with a dielectric thin film including the lithium niobate film epitaxially grown on the substrate is inexpensive compared to the lithium niobate single-crystal substrate.

However, in the optical waveguide element and the optical modulation element using the lithium niobate film epitaxially grown on the substrate, the thickness of the lithium niobate film may impose a limitation in the design of the optical waveguide element and the optical modulation element. In more detail, the lithium niobate film epitaxially grown on the substrate preferably has a sufficient film thickness such that an optical waveguide element and an optical modulation element that can be applied to a variety of light including visible light and infrared light are obtained. However, the lithium niobate film epitaxially grown on the substrate is susceptible to the occurrence of cracks, and there is a problem in that the thicker the film thickness is, the more the lithium niobate film is susceptible to the occurrence of cracks.

For this reason, a substrate with a dielectric thin film in which a lithium niobate film is less susceptible to the occurrence of cracks is desirable for the substrate with a dielectric thin film including the lithium niobate film epitaxially grown on the substrate.

The present invention has been accomplished in view of the above-described problem, and an object of the present invention is to provide a substrate with a dielectric thin film that has a lithium niobate film epitaxially grown on a substrate, has a lithium niobate film less susceptible to the occurrence of cracks, can be applied to a wide variety of light including visible light and infrared light, and is capable of forming an optical waveguide element and an optical modulation element with less optical loss.

Another object of the present invention is to provide an optical waveguide element and an optical modulation element with less optical loss that include a substrate with a dielectric thin film including a dielectric thin film made of a lithium niobate film, have the lithium niobate film less susceptible to the occurrence of cracks, and can be applied to a wide variety of light including visible light and infrared light.

A substrate with a dielectric thin film according to an aspect of the present invention includes a single-crystal substrate, a stress relaxation layer formed in contact with a main surface of the single-crystal substrate, and a dielectric thin film formed in contact with the stress relaxation layer, in which the stress relaxation layer is made of a c-axis-oriented epitaxial film, includes: a twin crystal structure of LiNbO₃ including a first crystal and a second crystal that is rotated 180° about a c-axis with respect to the first crystal; and a LiNb₃O₈ phase, the dielectric thin film is made of a lithium niobate film which is a c-axis-oriented epitaxial film, has the twin crystal structure of LiNbO₃, has a film thickness of 0.5 μm to 2 μm, and has a maximum domain width greater than a maximum domain width of the stress relaxation layer, and a percentage of a film thickness of the stress relaxation layer to the film thickness of the dielectric thin film is 5% to 25%.

The substrate with a dielectric thin film of the present invention includes the stress relaxation layer that is made of the c-axis-oriented epitaxial film formed in contact with the main surface of the single-crystal substrate, and includes: a twin crystal structure of LiNbO₃ including a first crystal and a second crystal that is rotated 180° about a c-axis with respect to the first crystal; and a LiNb₃O₈ phase, and the dielectric thin film formed in contact with the stress relaxation layer, the dielectric thin film is made of the lithium niobate film which is a c-axis-oriented epitaxial film, has the twin crystal structure of LiNbO₃, has the film thickness of 0.5 μm to 2 μm, and has the maximum domain width greater than the maximum domain width of the stress relaxation layer, and the percentage of the film thickness of the stress relaxation layer to the film thickness of the dielectric thin film is 5% to 25%. Accordingly, in the substrate with a dielectric thin film of the present invention, distortion and stress caused by a difference in lattice constant and a difference in coefficient of linear expansion between the single-crystal substrate and the lithium niobate film are absorbed in the stress relaxation layer and alleviated. For this reason, in the substrate with a dielectric thin film of the present invention, the lithium niobate film is less susceptible to the occurrence of cracks.

In the substrate with a dielectric thin film of the present invention, the dielectric thin film is made of the lithium niobate film which is the c-axis-oriented epitaxial film, and is less susceptible to the occurrence of cracks. Thus, the film thickness of the dielectric thin film can be set to a thickness equal to or greater than 0.5 μm suitable for manufacturing an optical waveguide element and an optical modulation element using the substrate with a dielectric thin film. Accordingly, the substrate with a dielectric thin film of the present invention can be preferably used for manufacturing an optical waveguide element and an optical modulation element that can be applied to a wide variety of light including visible light and infrared light.

In the substrate with a dielectric thin film of the present invention, the percentage of the film thickness of the stress relaxation layer to the film thickness of the dielectric thin film is equal to or less than 25%. Thus, the stress relaxation layer does not affect the characteristics of an optical waveguide element and an optical modulation element, and an optical waveguide element and an optical modulation element with less optical loss can be formed.

An optical waveguide element and an optical modulation element of the present invention include a substrate with a dielectric thin film including a lithium niobate film less susceptible to the occurrence of cracks. For this reason, in a manufacturing process of an optical waveguide element and/or the optical modulation element, for example, even if annealing is performed, the lithium niobate film of the substrate with a dielectric thin film is less susceptible to the occurrence of cracks, and excellent productivity is achieved. Furthermore, since the lithium niobate film of the substrate with a dielectric thin film is less susceptible to the occurrence of cracks, an optical waveguide element and an optical modulation element with excellent durability are provided.

The substrate with a dielectric thin film of the present invention includes the dielectric thin film made of the lithium niobate film having a sufficiently large film thickness, and the percentage of the film thickness of the stress relaxation layer to the film thickness of the dielectric thin film is appropriate. Thus, the optical waveguide element and the optical modulation element can be applied to a wide variety of light including visible light and infrared light, and have less optical loss.

### BRIEF DESCRIPTION OF THE DRAWINGS

FIG. 1 is a schematic cross-sectional view illustrating a substrate with a dielectric thin film 1 according to an embodiment of the present invention.

FIG. 2 is a plan view illustrating an example of an optical waveguide element 100 using the substrate with a dielectric thin film 1 illustrated in FIG. 1.

FIG. 3 is a cross-sectional view of the optical waveguide element 100 taken along line A-A′ in FIG. 2.

FIG. 4 is a plan view illustrating an example of a Mach-Zehnder optical modulation element 200A using the substrate with a dielectric thin film 1 illustrated in FIG. 1.

FIG. 5 is a cross-sectional view of the optical modulation element 200A taken along line B-B′ in FIG. 4.

FIG. 6A is a photograph illustrating an image obtained by mapping analysis of an interface between a single-crystal substrate 2 and a stress relaxation layer 31 of Example 5. FIG. 6A is a photograph of a first crystal 3a and a second crystal 3b that form a twin crystal structure of LiNbO₃ included in the stress relaxation layer 31.

FIG. 6B is a photograph illustrating an image obtained by mapping analysis of the interface between the single-crystal substrate 2 and the stress relaxation layer 31 of Example 5. FIG. 6B is a photograph of the first crystal 3a and the second crystal 3b that form the twin crystal structure of LiNbO₃ included in the stress relaxation layer 31.

FIG. 6C is a photograph of a LiNb₃O₈ phase 3c included in the stress relaxation layer 31.

FIG. 7A is a photograph illustrating an image obtained by mapping analysis of an interface between a single-crystal substrate 2 and a dielectric thin film 3 of Comparative Example 1. FIG. 7A is a photograph of a first crystal 3a and a second crystal 3b that form a twin crystal structure of LiNbO₃ included in the dielectric thin film 3.

FIG. 7B is a photograph illustrating an image obtained by mapping analysis of the interface between the single-crystal substrate 2 and the dielectric thin film 3 of Comparative Example 1. FIG. 7B is a photograph of the first crystal 3a and the second crystal 3b that form the twin crystal structure of LiNbO₃ included in the dielectric thin film 3.

FIG. 7C is a photograph of a LiNb₃O₈ phase 3c included in the dielectric thin film 3.

### DETAILED DESCRIPTION OF THE INVENTION

The present inventors have conducted intense studies as follows to solve the above-described problem and to suppress the occurrence of cracks in a lithium niobate film of a substrate with a dielectric thin film including a lithium niobate film epitaxially grown on a single-crystal substrate.

That is, in the substrate with a dielectric thin film in which the epitaxially grown lithium niobate film is formed in contact with the single-crystal substrate, large distortion and stress caused by a difference in lattice constant and a difference in coefficient of linear expansion between the single-crystal substrate and the lithium niobate film occur in an interface between the single-crystal substrate and the lithium niobate film.

For this reason, in the related art, in a manufacturing process of a substrate with a dielectric thin film, the lithium niobate film is susceptible to the occurrence of cracks in epitaxially growing a lithium niobate film. In addition, since the distortion and the stress described above are greater as the film thickness of the lithium niobate film is thicker, in a substrate with a dielectric thin film including a thicker lithium niobate film, the lithium niobate film is more susceptible to the occurrence of cracks during and after manufacturing. Furthermore, if a step such as annealing is performed in manufacturing an optical modulation element or the like using the substrate with a dielectric thin film, distortion and stress due to the difference in coefficient of linear expansion between the single-crystal substrate and the lithium niobate film are likely to be greater. For this reason, in manufacturing the optical modulation element or the like using the substrate with a dielectric thin film, the lithium niobate film is susceptible to the occurrence of cracks during and after manufacturing.

The present inventors have suggested a method for suppressing the occurrence of cracks in the lithium niobate film that uses, as a lithium niobate film, a c-axis-oriented epitaxial film having a twin crystal structure of LiNbO₃ including a first crystal and a second crystal that is rotated 180° about a c-axis with respect to the first crystal. In this case, it is estimated that the distortion and the stress caused by the difference in lattice constant and the difference in coefficient of linear expansion between the single-crystal substrate and the lithium niobate film are alleviated with the above-described twin crystal structure, so that the lithium niobate film is less susceptible to the occurrence of cracks.

However, even in a case where the c-axis-oriented epitaxial film having the twin crystal structure described above is used as the lithium niobate film, it is not possible to sufficiently suppress the occurrence of cracks in the lithium niobate film epitaxially grown on the single-crystal substrate. For this reason, it is desirable for a substrate with a dielectric thin film in which the occurrence of cracks in a lithium niobate film is further suppressed.

Accordingly, the present inventors have thought that the c-axis-oriented lithium niobate film having the above-described twin crystal structure may be epitaxially grown on the single-crystal substrate via a stress relaxation layer and have conducted intense studies focusing on deposition conditions of the lithium niobate film.

As a result, the present inventors have found that, before epitaxially growing the c-axis-oriented lithium niobate film having the above-described twin crystal structure on the single-crystal substrate, a stress relaxation layer that includes the above-described twin crystal structure and a LiNb₃O₈ phase and is made of a c-axis-oriented epitaxial film having a maximum domain width smaller than a maximum domain width of the lithium niobate film having the above-described twin crystal structure may be formed using a material having a large content of Nb and a small content of Li compared to a material used for forming the lithium niobate film having the above-described twin crystal structure.

It is estimated that, in a case where the c-axis-oriented lithium niobate film having the above-described twin crystal structure is epitaxially grown at a film thickness equal to or less than 2 μm in contact with the stress relaxation layer formed in such a manner, and a percentage of the film thickness of the stress relaxation layer to the film thickness of the epitaxially grown lithium niobate film is made to be equal to or greater than 5%, distortion and stress that occur in the interface between the single-crystal substrate and the lithium niobate film are alleviated with the stress relaxation layer having a sufficient film thickness with respect to the film thickness of the epitaxially grown lithium niobate film, and the occurrence of cracks in the lithium niobate film is suppressed.

In more detail, even in a case where the single-crystal substrate and the lithium niobate film are in contact with each other via the stress relaxation layer, distortion and stress caused by the difference in lattice constant and the difference in coefficient of linear expansion between the single-crystal substrate and the lithium niobate film occur. However, in a case where the single-crystal substrate and the lithium niobate film are in contact with each other via the stress relaxation layer, before cracks occur in the lithium niobate film due to the distortion and the stress described above, fine nanocracks that are an initial stage of cracks occur in the stress relaxation layer. The extension of nanocracks that occur in the stress relaxation layer is limited to within a range of the stress relaxation layer. With this, it is estimated that the distortion and the stress described above are absorbed in the stress relaxation layer and alleviated, and the occurrence of cracks in the lithium niobate film is suppressed.

The present inventors have found that the film thickness of the lithium niobate film grown in contact with the stress relaxation layer is set to be equal to or greater than 0.5 μm, so that the substrate with a dielectric thin film can be suitably used for manufacturing an optical waveguide element and an optical modulation element applicable to a wide variety of light including visible light and infrared light, and the percentage of the film thickness of the stress relaxation layer to the film thickness of the lithium niobate film is set to be equal to or less than 25%, so that the substrate with a dielectric thin film can form an optical waveguide element and an optical modulation element with sufficiently less optical loss.

The above-described stress relaxation layer is made of the c-axis-oriented epitaxial film having the maximum domain width smaller than the maximum domain width of the lithium niobate film having the above-described twin crystal structure, and includes the crystal structure of LiNbO₃ and the LiNb₃O₈ phase. Thus, satisfactory bonding to the c-axis-oriented lithium niobate film having the above-described twin crystal structure epitaxially grown thereon is achieved, and there is less influence on an optical modulation element including the substrate with a dielectric thin film.

In contrast, for example, in a case where an epitaxial buffer layer made of ZrO₂ that is a quite different material from lithium niobate is provided instead of the above-described stress relaxation layer, bonding defect to the lithium niobate film is likely to occur, and there is a significant influence on characteristics such as optical loss in an optical modulation element including the substrate with a dielectric thin film.

The present inventors have confirmed that, in the substrate with a dielectric thin film in which the single-crystal substrate and the lithium niobate film are in contact with each other via the above-described stress relaxation layer, the lithium niobate film is less susceptible to the occurrence of cracks even if annealing is performed, an optical waveguide element and an optical modulation element with less optical loss can be manufactured with satisfactory yield, and have conceived the present invention.

The present invention includes the following aspects.
[1] A substrate with a dielectric thin film including:
   a single-crystal substrate;
   a stress relaxation layer formed in contact with a main surface of the single-crystal substrate; and
   a dielectric thin film formed in contact with the stress relaxation layer,
   wherein the stress relaxation layer is made of a c-axis-oriented epitaxial film, and includes: a twin crystal structure of LiNbO₃ including a first crystal and a second crystal that is rotated 180° about a c-axis with respect to the first crystal; and a LiNb₃O₈ phase,
   the dielectric thin film is made of a lithium niobate film which is a c-axis-oriented epitaxial film, has the twin crystal structure of LiNbO₃, has a film thickness of 0.5 μm to 2 μm, and has a maximum domain width greater than a maximum domain width of the stress relaxation layer, and
   a percentage of a film thickness of the stress relaxation layer to the film thickness of the dielectric thin film is 5% to 25%.
[2] The substrate with a dielectric thin film according to [1],
   in which the maximum domain width of the stress relaxation layer is 20 nm to 70 nm.
[3] The substrate with a dielectric thin film according to [1],
   in which the single-crystal substrate is a sapphire single-crystal substrate the main surface of which is a c-plane.
[4] The substrate with a dielectric thin film according to [1],
   in which the twin crystal structure of the dielectric thin film has a ratio between a first diffraction intensity corresponding to the first crystal and a second diffraction intensity corresponding to the second crystal equal to or greater than 0.5 and equal to or less than 2.0 in pole measurement by an X-ray diffraction method.
[5] An optical waveguide element including:
   the substrate with a dielectric thin film according to any one of [1] to [4].
[6] An optical modulation element including:
   the substrate with a dielectric thin film according to any one of [1] to [4].

Hereinafter, a substrate with a dielectric thin film, an optical waveguide element, and an optical modulation element of the present embodiment will be described in detail with reference to the drawings as appropriate. In the drawings used in the following description, characteristic portions may be enlarged for convenience to make the features of the present invention easy to understand. Accordingly, the dimensional ratio or the like of each component is different from the actual one. Materials, dimensions, and the like illustrated in the following description are examples, and the present invention is not limited thereto, and can be changed and implemented as appropriate without departing from the spirit of the present invention.

Substrate with a Dielectric Thin Film

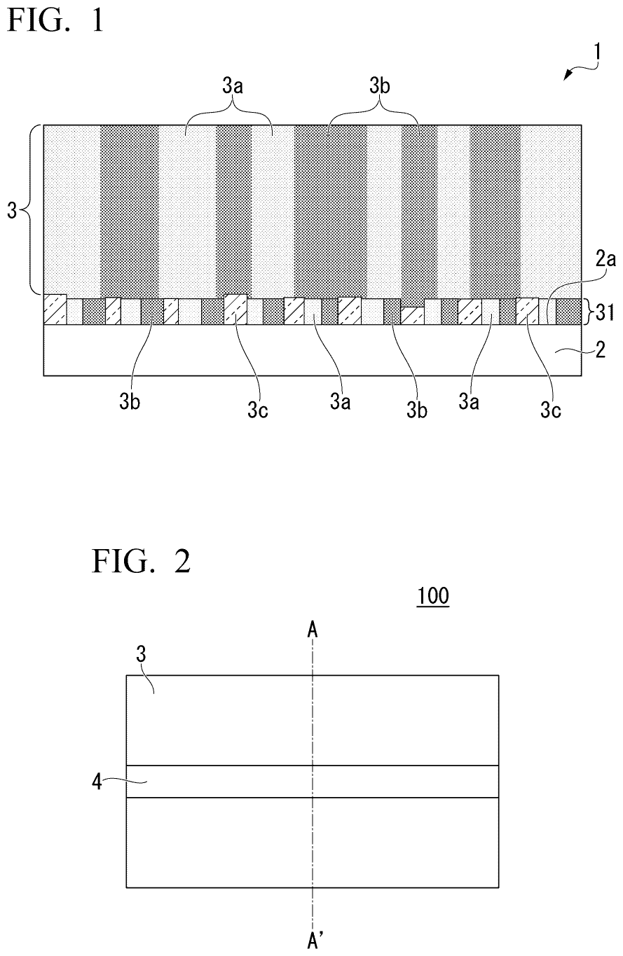

FIG. 1 is a schematic cross-sectional view illustrating a substrate with a dielectric thin film 1 according to an embodiment of the present invention. As illustrated in FIG. 1, the substrate with a dielectric thin film 1 of the present embodiment includes a single-crystal substrate 2, a stress relaxation layer 31 formed in contact with a main surface 2a of the single-crystal substrate 2, and a dielectric thin film 3 formed in contact with the stress relaxation layer 31.

The stress relaxation layer 31 in the substrate with a dielectric thin film 1 of the present embodiment is made of a c-axis-oriented epitaxial film, and includes a twin crystal structure of LiNbO₃ described below and a LiNb₃O₈ phase 3c.

The dielectric thin film 3 in the substrate with a dielectric thin film 1 of the present embodiment is made of a lithium niobate film which is a c-axis-oriented epitaxial film, has a twin crystal structure of LiNbO₃ similar to the twin crystal structure of LiNbO₃ of the stress relaxation layer 31, has a film thickness of 0.5 μm to 2 μm, and has a maximum domain width greater than a maximum domain width of the stress relaxation layer 31.

In the substrate with a dielectric thin film 1 of the present embodiment, a percentage of a film thickness of the stress relaxation layer 31 to the film thickness of the dielectric thin film 3 is 5% to 25%.

### Single-Crystal Substrate 2

As the single-crystal substrate 2, a substrate in which the stress relaxation layer 31 including the twin crystal structure of LiNbO₃ and the LiNb₃O₈ phase 3c can be formed as an epitaxial film may be used, and a known single-crystal substrate can be used. The single-crystal substrate 2 preferably has a refractive index lower than that of lithium niobate (LiNbO₃), and for example, a sapphire single-crystal substrate or a silicon single-crystal substrate can be used.

In the substrate with a dielectric thin film 1 of the present embodiment, as the single-crystal substrate 2, a sapphire single-crystal substrate is particularly preferably used. The sapphire single-crystal substrate has a refractive index lower than that of LiNbO₃. Thus, for example, in a case where the dielectric thin film 3 of the substrate with a dielectric thin film 1 is used as an optical waveguide layer of an optical modulation element, the sapphire single-crystal substrate can serve as a cladding layer. Accordingly, in a case where the single-crystal substrate 2 is the sapphire single-crystal substrate, the dielectric thin film 3 can be suitably used as an optical waveguide layer of an optical modulation element without separately providing a cladding layer between the single-crystal substrate 2 and the dielectric thin film 3.

The stress relaxation layer 31 in the substrate with a dielectric thin film 1 of the present embodiment and the dielectric thin film 3 formed over the single-crystal substrate 2 via the stress relaxation layer 31 is easily formed as a c-axis-oriented epitaxial film with respect to the single-crystal substrate 2 of various crystal orientations. For this reason, the crystal orientation of the single-crystal substrate 2 is not particularly limited.

In the substrate with a dielectric thin film 1 of the present embodiment, the stress relaxation layer 31 is made of the c-axis-oriented epitaxial film, and includes the twin crystal structure of LiNbO₃ and the LiNb₃O₈ phase 3c, and the dielectric thin film 3 that is formed over the single-crystal substrate 2 via the stress relaxation layer 31 is made of the lithium niobate film which is a c-axis-oriented epitaxial film, has the twin crystal structure of LiNbO₃, and has three-fold symmetry. For this reason, it is desirable that the crystal orientation of the main surface 2a of the single-crystal substrate 2 has the same symmetry as the dielectric thin film 3. Accordingly, for example, in a case where a sapphire single-crystal substrate is used as the single-crystal substrate 2, the main surface 2a is preferably a c-plane. For example, in a case where a silicon single-crystal substrate is used as the single-crystal substrate 2, the main surface 2a is preferably a (111) plane.

### Stress Relaxation Layer 31

The stress relaxation layer 31 is made of a c-axis-oriented epitaxial film. An epitaxial film forming the stress relaxation layer 31 contains lithium niobate (LiNbO₃) as a main component. Since lithium niobate has a large electro-optical constant, lithium niobate is suitably used as a material of an optical waveguide layer or the like of an optical modulation element.

In a composition of the epitaxial film forming the stress relaxation layer 31, a composition of the twin crystal structure of LiNbO₃ and a composition of the LiNb₃O₈ phase 3c coexist. For this reason, the composition of the epitaxial film forming the stress relaxation layer 31 has a small amount of Li₂O in a percentage corresponding to a content of LiNb₃O₈ phase 3c with respect to the composition of the twin crystal structure of LiNbO₃. Specifically, in the composition of the epitaxial film forming the stress relaxation layer 31, the amount of Li₂O is preferably small in a percentage of 35 to 48% by mol with respect to the composition of the twin crystal structure of LiNbO₃.

The stress relaxation layer 31 includes the twin crystal structure of LiNbO₃ and the LiNb₃O₈ phase 3c. The twin crystal structure of LiNbO₃ forming the stress relaxation layer 31 includes a first crystal 3a and a second crystal 3b existing at a position obtained by rotating the first crystal 3a 180° about a c-axis. As illustrated in FIG. 1, all the first crystal 3a, the second crystal 3b, and the LiNb₃O₈ phase 3c forming the stress relaxation layer 31 are grown substantially vertically with respect to the main surface 2a of the single-crystal substrate 2.

In the present embodiment, the first crystal 3a included in the twin crystal structure of LiNbO₃ forming the stress relaxation layer 31 indicates the crystal of LiNbO₃ having the same in-plane orientation as the in-plane orientation of the single-crystal substrate 2. The second crystal 3b indicates the crystal of LiNbO₃ having the in-plane orientation rotated by 180° with respect to the in-plane orientation of the single-crystal substrate 2.

Both the first crystal 3a and the second crystal 3b forming the stress relaxation layer 31 are close to a single crystal. However, if the first crystal 3a and the second crystal 3b are too close to a perfect single crystal, the effect of alleviating distortion and stress caused by the difference in lattice constant and the difference in coefficient of linear expansion between the single-crystal substrate 2 and the lithium niobate film forming the dielectric thin film 3 with the above-described twin crystal structure is reduced, and the lithium niobate film may be susceptible to the occurrence of cracks. For this reason, for both the first crystal 3a and the second crystal 3b, a full width at half maximum of a rocking curve of (006) reflection measured by an X-ray diffraction method preferably falls within a range equal to or greater than 0.3° and equal to or less than 0.6°. In a case where the full width at half maximum of the rocking curve of (006) reflection of the first crystal 3a and the second crystal 3b falls within this range, the first crystal 3a and the second crystal 3b can be optically regarded as a single crystal. Besides, the first crystal 3a and the second crystal 3b are not too close to a prefect single crystal, and the occurrence of cracks in the lithium niobate film can be effectively suppressed.

A percentage of an area of the twin crystal structure of LiNbO₃ to a total area of the twin crystal structure of LiNbO₃ and the LiNb₃O₈ phase 3c included in the epitaxial film forming the stress relaxation layer 31 in a cross-sectional view can be set within a range of, for example, 0.6 to 0.95, and is preferably within a range of 0.7 to 0.9. A percentage of an area of the LiNb₃O₈ phase 3c to the above-described total area can be set within a range of, for example, 0.05 to 0.4, and is preferably within a range of 0.1 to 0.3.

If the percentage of the area of the twin crystal structure of LiNbO₃ to the total area of the twin crystal structure of LiNbO₃ and the LiNb₃O₈ phase 3c included in the epitaxial film forming the stress relaxation layer 31 in a cross-sectional view is equal to or greater than 0.6 (in other words, the percentage of the area of the LiNb₃O₈ phase 3c to the above-described total area is equal to or less than 0.4), the crystal orientation of the lithium niobate film of the dielectric thin film 3 formed on the stress relaxation layer 31 is easily oriented in alignment with the crystal orientation of the stress relaxation layer 31. Accordingly, in a case where the stress relaxation layer 31 uses the dielectric thin film 3 of the substrate with a dielectric thin film 1 as an optical waveguide layer of an optical modulation element, there is less influence on the characteristics such as optical loss of the optical modulation element.

If the percentage of the area of the twin crystal structure of LiNbO₃ to the total area of the twin crystal structure of LiNbO₃ and the LiNb₃O₈ phase 3c included in the epitaxial film forming the stress relaxation layer 31 in a plan view is equal to or less than 0.95 (in other words, the percentage of the area of the LiNb₃O₈ phase 3c to the above-described total area is equal to or greater than 0.05), the LiNb₃O₈ phase 3c is sufficiently included. Thus, the maximum domain width of the stress relaxation layer 31 is easily made small. As a result, the effect of alleviating distortion and stress caused by the difference in lattice constant and the difference in coefficient of linear expansion between the single-crystal substrate 2 and the lithium niobate film forming the dielectric thin film 3 with the stress relaxation layer 31 is prominently exhibited. Accordingly, the occurrence of cracks in the lithium niobate film can be more effectively suppressed.

The percentages of the area of the twin crystal structure of LiNbO₃ and the area of the LiNb₃O₈ phase 3c to the total area of the twin crystal structure of LiNbO₃ and the LiNb₃O₈ phase 3c included in the epitaxial film forming the stress relaxation layer 31 in a cross-sectional view can be calculated by a method described below, for example.

A cross section of the substrate with a dielectric thin film 1 is observed at a magnification of 100,000 to 400,000 with a scanning transmission electron microscope (manufactured by FEI Corporation). With the use of the scanning transmission electron microscope, an image in which the twin crystal structure of LiNbO₃ and the LiNb₃O₈ phase 3c can be clearly distinguished is obtained. In the obtained image, the area of the twin crystal structure of LiNbO₃ and the area of the LiNb₃O₈ phase 3c that exist within a range of a length of 200 nm to 800 nm on the interface between the single-crystal substrate 2 and the stress relaxation layer 31 are measured. Based on the results, the percentage of the area of the twin crystal structure of LiNbO₃ and the percentage of the area of the LiNb₃O₈ phase 3c to the total area of the area of the twin crystal structure of LiNbO₃ and the area of the LiNb₃O₈ phase 3c are calculated, respectively.

For the twin crystal structure of LiNbO₃ of the stress relaxation layer 31 of the present embodiment, in pole measurement by an X-ray diffraction method, a ratio between a first diffraction intensity corresponding to the first crystal 3a and a second diffraction intensity corresponding to the second crystal 3b is preferably equal to or greater than 0.5 and equal to or less than 2.0, is more preferably equal to or greater than 0.8 and equal to or less than 1.25, and is preferably closer to 1.0. In the pole measurement by the X-ray diffraction method, the ratio between the first diffraction intensity corresponding to the first crystal 3a and the second diffraction intensity corresponding to the second crystal 3b corresponds to a percentage of the first crystal 3a and the second crystal 3b.

The percentage of the first crystal 3a and the second crystal 3b in the stress relaxation layer 31 is preferably even. This is because, as the percentage of the first crystal 3a and the second crystal 3b in the twin crystal structure of LiNbO₃ of the stress relaxation layer 31 is more even, a percentage of a first crystal 3a and a second crystal 3b in the twin crystal structure of LiNbO₃ of the dielectric thin film 3 is more easily made even. As the percentage of the first crystal 3a and the second crystal 3b in the twin crystal structure of LiNbO₃ of the dielectric thin film 3 is more even, distortion and stress caused by the difference in lattice constant and the difference in coefficient of linear expansion between the single-crystal substrate 2 and the lithium niobate film can be effectively alleviated with the above-described twin crystal structure. Accordingly, the lithium niobate film is less susceptible to the occurrence of cracks.

The epitaxial film forming the stress relaxation layer 31 may be made only of the twin crystal structure of LiNbO₃ and the LiNb₃O₈ phase 3c or may include the twin crystal structure of LiNbO₃ and a phase other than the LiNb₃O₈ phase 3c, and is preferably made only of the twin crystal structure of LiNbO₃ and the LiNb₃O₈ phase 3c.

The maximum domain width of the stress relaxation layer 31 is smaller than the maximum domain width of the dielectric thin film 3 (in other words, the maximum domain width of the dielectric thin film 3 is greater than that of the stress relaxation layer 31). With this, in the substrate with a dielectric thin film 1 of the present embodiment, distortion and stress that occur in the interface between the single-crystal substrate 2 and the dielectric thin film 3 are alleviated with the stress relaxation layer 31.

In the present embodiment, the maximum domain width of the stress relaxation layer 31 means a dimension described below. That is, a maximum domain width in a direction perpendicular to a thickness direction is measured on each first crystal 3a, each second crystal 3b, and the LiNb₃O₈ phase 3c that exist within the range of the length of 200 nm to 800 nm on the interface between the single-crystal substrate 2 and the stress relaxation layer 31 and are included in the twin crystal structure of LiNbO₃, and a maximum dimension among the maximum domain widths of a plurality of first crystals 3a, a plurality of second crystals 3b, and a plurality of LiNb₃O₈ phases 3c existing within the range of the length of 200 nm to 800 nm extracted from the results is the maximum domain width of the stress relaxation layer 31.

In the present embodiment, the maximum domain width is used as an index of a domain width of the stress relaxation layer 31. This is because the maximum domain width of the stress relaxation layer 31 can be easily and accurately measured compared to an average value of domain widths, for example. The reason is that the first crystal 3a, the second crystal 3b, and the LiNb₃O₈ phase 3c included in the twin crystal structure of LiNbO₃ of the stress relaxation layer 31 include a very narrow domain width. In more detail, the reason is that it is not easy to discriminate each first crystal 3a, each second crystal 3b, and each LiNb₃O₈ phase 3c included in the twin crystal structure of LiNbO₃ and to measure the domain widths thereof to obtain an average value of the domain widths of the stress relaxation layer 31.

In the present embodiment, the maximum domain width of the dielectric thin film 3 means a dimension described below. That is, a maximum domain width in a direction perpendicular to a thickness direction is measured on each first crystal 3a and each second crystal 3b that exist within the range of the length of 200 nm to 800 nm on the interface between the single-crystal substrate 2 and the stress relaxation layer 31 and are included in the twin crystal structure of LiNbO₃, and a maximum dimension of the maximum domain widths of a plurality of first crystals 3a and a plurality of second crystals 3b existing within the range of the length of 200 nm to 800 nm extracted from the results is the maximum domain width of the dielectric thin film 3.

In the present embodiment, the maximum domain width of the stress relaxation layer 31 is preferably 20 nm to 70 nm. If the maximum domain width of the stress relaxation layer 31 is equal to or greater than 20 nm, it is preferable since the domains of the stress relaxation layer 31 epitaxially grown on the main surface 2a of the single-crystal substrate 2 are difficult to interrupt, and the stress relaxation layer 31 having a uniform thickness is easily formed. If the maximum domain width of the stress relaxation layer 31 is equal to or less than 70 nm, distortion and stress caused by the difference in lattice constant and the difference in coefficient of linear expansion between the single-crystal substrate 2 and the lithium niobate film forming the dielectric thin film 3 can be effectively alleviated with the stress relaxation layer 31. Accordingly, the lithium niobate film is still less susceptible to the occurrence of cracks. The maximum domain width of the stress relaxation layer 31 is more desirably 20 nm to 50 nm, and is further desirably 20 nm to 40 nm.

### Dielectric Thin Film 3

The dielectric thin film 3 is made of a lithium niobate film which is a c-axis-oriented epitaxial film. The lithium niobate film forming the dielectric thin film 3 contains lithium niobate (LiNbO₃) as a main component. Since lithium niobate has a large electro-optical constant, lithium niobate is suitably used as a material of an optical waveguide layer or the like of an optical modulation element.

A composition of the lithium niobate film forming the dielectric thin film 3 is represented by a general formula LixNbAyOz (In the formula, A is an element other than Li, Nb, and O. x is 0.5 to 1.2, y is 0 to 0.5, and z is 1.5 to 4).

In the formula, A represents an element other than Li, Nb, and O. Examples of the element represented by A include K, Na, Rb, Cs, Be, Mg, Ca, Sr, Ba, Ti, Zr, Hf, V, Cr, Mo, W, Fe, Co, Ni, Zn, Sc, and Ce. The element represented by A may be one kind or may be two kinds or more.

In the formula, x is 0.5 to 1.2, and is preferably 0.9 to 1.05.

In the formula, y is 0 to 0.5.

In the formula, z is 1.5 to 4, and is preferably 2.5 to 3.5.

Similarly to the epitaxial film forming the above-described stress relaxation layer 31, the lithium niobate film forming the dielectric thin film 3 has a twin crystal structure of LiNbO₃ including a first crystal 3a and a second crystal 3b that is rotated 180° about a c-axis with respect to the first crystal; and a LiNb₃O₈ phase.

Similarly to the twin crystal structure of LiNbO₃ included in the epitaxial film forming the above-described stress relaxation layer 31, for the twin crystal structure of LiNbO₃ in the lithium niobate film forming the dielectric thin film 3, in both the first crystal 3a and the second crystal 3b, a full width at half maximum of a rocking curve of (006) reflection measured by an X-ray diffraction method is preferably within a range equal to greater than 0.3° and equal to or less than 0.6°.

For the twin crystal structure of LiNbO₃ in the lithium niobate film forming the dielectric thin film 3, in pole measurement by an X-ray diffraction method, a ratio between a first diffraction intensity corresponding to the first crystal 3a and a second diffraction intensity corresponding to the second crystal 3b is preferably equal to or greater than 0.5 and equal to or less than 2.0. As the percentage of the first crystal 3a and the second crystal 3b in the twin crystal structure of LiNbO₃ of the dielectric thin film 3 is more even, distortion and stress caused by the difference in lattice constant and the difference in coefficient of linear expansion between the single-crystal substrate 2 and the lithium niobate film can be more effectively alleviated with the above-described twin crystal structure. Accordingly, the lithium niobate film is less susceptible to the occurrence of cracks. The above-described ratio in the dielectric thin film 3 is more preferably equal to or greater than 0.8 and equal to or less than 1.25, and is preferably closer to 1.0.

For the twin crystal structure of LiNbO₃ in the lithium niobate film forming the dielectric thin film 3, the first crystal 3a and the second crystal 3b are preferably bonded to each other not via a grain boundary. If the grain boundary exists at the boundary between the first crystal 3a and the second crystal 3b, light scattering occurs on the boundary surface. For this reason, in a case where the dielectric thin film 3 of the substrate with a dielectric thin film 1 is used as an optical waveguide layer of an optical modulation element, the optical loss of the optical modulation element increases. In contrast, if the first crystal 3a and the second crystal 3b are bonded to each other, and no grain boundary exists at the boundary between the first crystal 3a and the second crystal 3b, the first crystal 3a and the second crystal 3b have the same refractive index, so that light scattering does not occur. Accordingly, optical characteristics equivalent to a case where the lithium niobate film is a single crystal are obtained.

It is desirable that the lithium niobate film forming the dielectric thin film 3 is a single phase made of twin crystals of LiNbO₃. The lithium niobate film forming the dielectric thin film 3 may include a LiNb₃O₈ phase 3c within a range in which there is no influence on characteristics such as optical loss of an optical modulation element in a case where the dielectric thin film 3 of the substrate with a dielectric thin film 1 is used as an optical waveguide layer of an optical modulation element.

The LiNb₃O₈ phase 3c in a case where the LiNb₃O₈ phase 3c is included in the lithium niobate film forming the dielectric thin film 3 is not grown in a direction substantially vertically with respect to the main surface 2a of the single-crystal substrate 2. In contrast, as illustrated in FIG. 1, the LiNb₃O₈ phase 3c forming the stress relaxation layer 31 is grown substantially vertically with respect to the main surface 2a of the single-crystal substrate 2. Accordingly, even in a case where the LiNb₃O₈ phase 3c is included in the lithium niobate film forming the dielectric thin film 3, the dielectric thin film 3 and the stress relaxation layer 31 can be easily distinguished.

The film thickness of the dielectric thin film 3 is equal to or greater than 0.5 km. Since the film thickness of the dielectric thin film 3 is equal to or greater than 0.5 μm, the dielectric thin film 3 of the substrate with a dielectric thin film 1 is used as an optical waveguide layer of an optical modulation element, the optical modulation element can be applied to a wide variety of light including visible light and infrared light.

The film thickness of the dielectric thin film 3 is equal to or less than 2 km. Since the film thickness of the dielectric thin film 3 is equal to or less than 2 μm, the occurrence of cracks in the lithium niobate film forming the dielectric thin film 3 can be effectively suppressed.

In the substrate with a dielectric thin film 1 of the present embodiment, a percentage ((stress relaxation layer 31/dielectric thin film 3)×100(%)) of the film thickness of the stress relaxation layer 31 to the film thickness of the dielectric thin film 3 is equal to or greater than 5%. Since the percentage of the film thickness of the stress relaxation layer 31 to the film thickness of the dielectric thin film 3 is equal to or greater than 5%, distortion and stress caused by the difference in lattice constant and the difference in coefficient of linear expansion between the single-crystal substrate 2 and the lithium niobate film forming the dielectric thin film 3 can be effectively alleviated with the stress relaxation layer 31. Accordingly, the lithium niobate film is less susceptible to the occurrence of cracks.

The percentage of the film thickness of the stress relaxation layer 31 to the film thickness of the dielectric thin film 3 is equal to or less than 25%. Since the percentage of the film thickness of the stress relaxation layer 31 to the film thickness of the dielectric thin film 3 is equal to or less than 25%, in a case where the dielectric thin film 3 of the substrate with a dielectric thin film 1 is used as an optical waveguide layer of an optical modulation element, the stress relaxation layer 31 does not influence characteristics such as optical loss of the optical modulation element. The percentage of the film thickness of the stress relaxation layer 31 to the film thickness of the dielectric thin film 3 is desirably 5% to 20%, and is more desirably 5% to 15%.

In the substrate with a dielectric thin film 1 of the present embodiment, the stress relaxation layer 31 and the dielectric thin film 3 are epitaxial films deposited by epitaxial growth. Accordingly, the crystal orientation of the lithium niobate film forming the dielectric thin film 3 is oriented in alignment with the crystal orientations of the single-crystal substrate 2 as a base and the stress relaxation layer 31 as a base film. In more detail, when a film plane of the lithium niobate film forming the dielectric thin film 3 is defined as an X-Y plane, and a film thickness direction is defined as a Z axis, a crystal of the single-crystal substrate 2, a crystal of the epitaxial film forming the stress relaxation layer 31, and a crystal of the epitaxial film forming the dielectric thin film 3 are oriented in alignment in X-axis, Y-axis, and Z-axis directions.

The stress relaxation layer 31 and the dielectric thin film 3 being the epitaxial films can be verified by first confirming a peak intensity at an orientation position by 2θ-θ X-ray diffraction and secondly confirming a pole in pole measurement, for example.

Specifically, in verifying that the stress relaxation layer 31 and the dielectric thin film 3 are the epitaxial films, as a first condition, when measurement by 2θ-θ X-ray diffraction is performed, a peak intensity of all peaks other than a target surface needs to be equal to or less 10% and preferably, equal to or less than 5%, of a maximum peak intensity of the target surface. In the c-axis-oriented epitaxial film forming the stress relaxation layer 31 and the dielectric thin film 3, a peak intensity of planes other than a (00L) plane is equal to or less than 10%, and preferably, equal to or less than 5%, of a maximum peak intensity of the (00L) plane. (00L) is a generic term for equivalent planes such as (001) and (002).

Under the above-described condition of confirming the peak intensity at the orientation position by 2θ-θ X-ray diffraction, only orientation in a single direction is shown. Accordingly, even if the above-described first condition is satisfied, in a case where the in-plane crystal orientation is not aligned, an intensity of X-rays is not increased at a specific angle position, and no pole is observed.

Accordingly, in verifying that the stress relaxation layer 31 and the dielectric thin film 3 are the epitaxial films, as a second condition, a pole needs to be observed in the pole measurement.

Since LiNbO₃ is a trigonal crystal structure, single-crystal LiNbO₃ (014) has three poles. In a case where the lithium niobate film is epitaxially grown, it is known that the lithium niobate film is epitaxially grown in a so-called twin crystal state in which crystals rotated by 180° about the c-axis are symmetrically coupled. In this case, since two of three poles are symmetrically coupled, there are six poles.

In the substrate with a dielectric thin film 1 of the present embodiment, for the c-axis of the epitaxial film forming the stress relaxation layer 31 and the c-axis of the lithium niobate film forming the dielectric thin film 3, for example, in a case where a sapphire single-crystal substrate the main surface 2a of which is a c-plane is used as the single-crystal substrate 2, the c-axis of each of the stress relaxation layer 31 and the dielectric thin film 3 and the c-axis of the single-crystal substrate 2 preferably have a deviation equal to or less than 5°, and preferably, completely coincide with each other. If the deviation between the c-axis of each of the stress relaxation layer 31 and the dielectric thin film 3 and the c-axis of the single-crystal substrate 2 is equal to or less than 5°, no practical problem occurs in characteristics of an optical modulation element using the substrate with a dielectric thin film 1.

Manufacturing Method of Substrate with a Dielectric Thin Film

Next, a manufacturing method of the substrate with a dielectric thin film 1 of the present embodiment will be described in connection with an example.

In manufacturing the substrate with a dielectric thin film 1 of the present embodiment, first, the stress relaxation layer 31 is formed in contact with the main surface 2a of the single-crystal substrate 2 (stress relaxation layer deposition step). Thereafter, the dielectric thin film 3 is formed in contact with the stress relaxation layer 31 (dielectric thin film deposition step).

### Stress Relaxation Layer Deposition Step

In the stress relaxation layer deposition step, the stress relaxation layer 31 is deposited by a method of epitaxially growing the epitaxial film on the main surface 2a of the single-crystal substrate 2. As the deposition method of the stress relaxation layer 31, for example, a sputtering method, a vacuum vapor deposition method, a pulse laser ablation (PLD) method, a chemical vapor deposition method (CVD), or a sol-gel method can be used.

As the deposition method of the stress relaxation layer 31, the sputtering method among the above-described methods is preferably used. This is because the stress relaxation layer 31 is deposited using the sputtering method, so that a single-domain polarization structure is obtained while deposition is performed without special treatment after deposition. This is because heat applied during sputtering and an electric field generated by self-bias serve as polarization processing. When polarization is distributed, electro-optical effects are caused to be reduced. If the stress relaxation layer 31 is formed in the single-domain polarization structure, an electro-optical coefficient similar to that obtained in the single crystal can be obtained.

In a case where the sputtering method is used as the deposition method of the stress relaxation layer 31, a target having a composition for obtaining an intended film composition is used. Specifically, for example, a target having a composition within a range of Li/(Li+Nb)=48% to 51% can be used.

The target can be manufactured by the following method, for example. As a raw material, for example, a raw material made of a sintered body containing Li₂CO₃ and Nb₂O₅ having purity equal to or greater than 3N as main raw materials is prepared. Next, the raw material is pulverized and blended using a ball mill with a ball made of ZrO₂, and a target powder material is obtained. The obtained target powder material is sintered using a known method, and the target is obtained.

In the manufacturing process of the target, if the raw material is pulverized using the above-described ball mill, the ball made of ZrO₂ is scraped. For this reason, Zr of about several hundred ppm is mixed into the target powder material obtained after the raw material is pulverized and blended. Accordingly, Zr is mixed into the target obtained by sintering the target powder material. However, since an amount of Zr contained in the target is small, the stress relaxation layer 31 can be epitaxially grown on the main surface 2a of the single-crystal substrate 2 using the target into which Zr is mixed, by the sputtering method without hindrance. Accordingly, no problem occurs due to Zr mixed into the target.

A shape of the target used in the deposition of the stress relaxation layer 31 is not particularly limited. The target preferably has a circular shape having a plane area two times or greater than the single-crystal substrate 2 since the stress relaxation layer 31 having a uniform film thickness is obtained. The deposition of the stress relaxation layer 31 is preferably performed while disposing the target coaxially with the single-crystal substrate 2 since the stress relaxation layer 31 having a uniform film thickness is obtained.

In a case where the sputtering method is used as the deposition method of the stress relaxation layer 31, for example, sputtering can be performed under conditions that mixture gas of Ar and O₂ is used as sputter gas, a percentage of O₂ in the sputter gas is set to 35% to 65%, a gas pressure is set to 0.08 Pa to 0.3 Pa, a temperature of the single-crystal substrate 2 is set to 450 to 700° C., and power of 1500 to 2000 W is applied such that a deposition rate is 300 to 180° nm/h.

The stress relaxation layer 31 is preferably deposited in a so-called single step without changing the deposition conditions in the middle.

### Dielectric Thin Film Deposition Step

In the dielectric thin film deposition step, the dielectric thin film 3 is deposited by a method of epitaxially growing the epitaxial film on the stress relaxation layer 31. As the deposition method of the dielectric thin film 3, for example, a sputtering method, a vacuum vapor deposition method, a pulse laser ablation (PLD) method, a chemical vapor deposition method (CVD), or a sol-gel method can be used.

As the deposition method of the dielectric thin film 3, the sputtering method among the above-described methods is preferably used. This is because the dielectric thin film 3 is deposited using the sputtering method, so that a single-domain polarization structure is obtained while deposition is performed without special treatment after deposition. This is because heat applied during sputtering and an electric field generated by self-bias serve as polarization processing. If polarization is distributed, electro-optical effects are caused to be reduced. If the stress relaxation layer 31 is formed in the single-domain polarization structure, an electro-optical coefficient similar to that obtained in the single crystal can be obtained.

In a case where the sputtering method is used as the deposition method of the dielectric thin film 3, for example, a target having a composition within a range of Li/(Li+Nb)=48% to 51% can be used.

As a manufacturing method of a target that is used in the deposition of the dielectric thin film 3, a known method can be used, and for example, the target can be manufactured using a method similar to the method of manufacturing the target used in the deposition of the stress relaxation layer 31.

A shape of the target used in the deposition of the dielectric thin film 3 is not particularly limited. The target preferably has a circular shape having a plane area two times or greater than the single-crystal substrate 2 since the dielectric thin film 3 having a uniform film thickness. The deposition of the dielectric thin film 3 is preferably performed while disposing the target coaxially with the single-crystal substrate 2 since the dielectric thin film 3 having a uniform film thickness is obtained.

In a case where the sputtering method is used as the deposition method of the dielectric thin film 3, for example, sputtering can be performed under conditions that mixture gas of Ar and O₂ is used as sputter gas, a ratio of O₂ in the sputter gas is set to 35% to 65%, a gas pressure is set to 0.08 Pa to 0.5 Pa, a temperature of the single-crystal substrate 2 is set to 450 to 700° C., and power of 1500 to 2000 W is applied such that a deposition rate is 300 to 180° nm/h.

The dielectric thin film 3 is preferably deposited in a so-called single step without changing the deposition conditions in the middle.

The deposition of the dielectric thin film 3 is preferably successively deposited by the sputtering method after the stress relaxation layer 31 is deposited by the sputtering method, similarly to the deposition method of the stress relaxation layer 31, except that the conditions of the ratio of O₂ in the sputter gas and the gas pressure are changed.

Specifically, the dielectric thin film 3 can be deposited by decreasing the ratio of O₂ in the sputter gas and increasing the gas pressure during sputtering after the stress relaxation layer 31 is deposited.

With the above steps, the substrate with a dielectric thin film 1 of the present embodiment is obtained.

In the substrate with a dielectric thin film 1 of the present embodiment, distortion and stress caused by the difference in lattice constant and the difference in coefficient of linear expansion between the single-crystal substrate 2 and the lithium niobate film forming the dielectric thin film 3 are absorbed in the stress relaxation layer 31 and alleviated. For this reason, in the substrate with a dielectric thin film 1 of the present embodiment, the lithium niobate film is less susceptible to the occurrence of cracks.

### Optical Waveguide Element

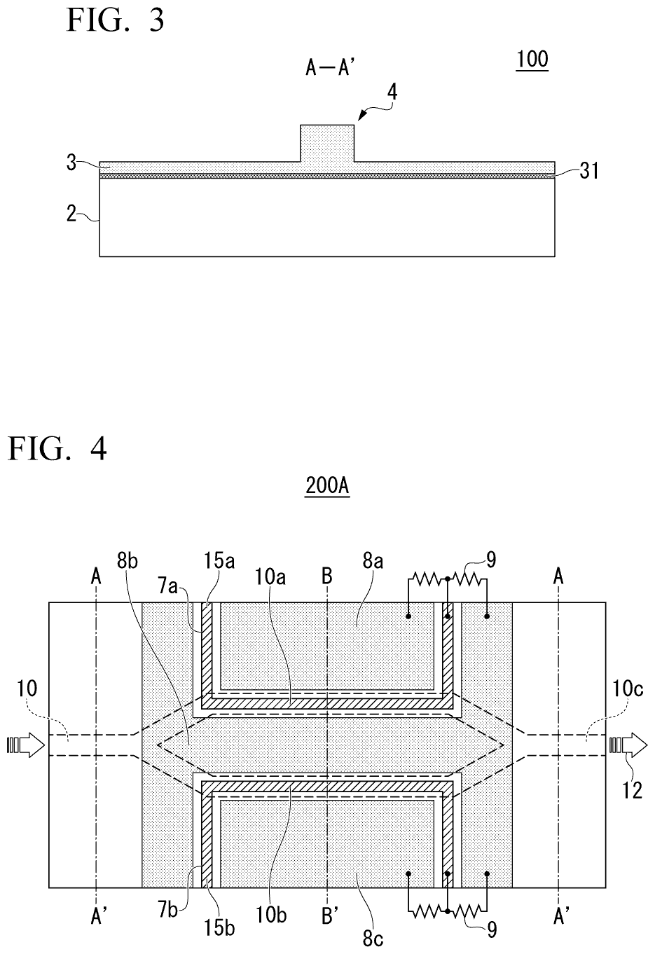

FIG. 2 is a plan view illustrating an example of an optical waveguide element 100 using the substrate with a dielectric thin film 1 illustrated in FIG. 1. FIG. 3 is a cross-sectional view of the optical waveguide element 100 taken along line A-A′ in FIG. 2.

In the optical waveguide element 100 illustrated in FIGS. 2 and 3, the same members as those in the substrate with a dielectric thin film 1 illustrated in FIG. 1 are represented by the same reference signs, and description thereof will not be repeated.

The optical waveguide element 100 illustrated in FIGS. 2 and 3 has a ridge portion 4 that is formed by processing the dielectric thin film 3 in the substrate with a dielectric thin film 1 illustrated in FIG. 1 in a ridge shape (protrusion-like shape). The ridge portion 4 of the optical waveguide element 100 is a portion where target light propagates in a TM fundamental mode.

The optical waveguide element 100 illustrated in FIGS. 2 and 3 can be manufactured by processing the dielectric thin film 3 in the substrate with a dielectric thin film 1 illustrated in FIG. 1 in a ridge shape (protrusion-like shape). As the method of processing the dielectric thin film 3 in a ridge shape, a known method such as an etching method can be used.

The optical waveguide element 100 illustrated in FIGS. 2 and 3 includes the substrate with a dielectric thin film 1 illustrated in FIG. 1. For this reason, the lithium niobate film forming the dielectric thin film 3 of the substrate with a dielectric thin film 1 is less susceptible to the occurrence of cracks, and excellent productivity is achieved. Since the lithium niobate film forming the dielectric thin film 3 of the substrate with a dielectric thin film 1 is less susceptible to the occurrence of cracks, the optical waveguide element 100 with excellent durability is provided. In the optical waveguide element 100 illustrated in FIGS. 2 and 3, the dielectric thin film 3 has a sufficiently large film thickness, and the percentage of the film thickness of the stress relaxation layer 31 to the film thickness of the dielectric thin film 3 is appropriate. Thus, the optical waveguide element 100 can be applied to a wide variety of light including visible light and infrared light, and has less optical loss.

### Optical Modulation Element

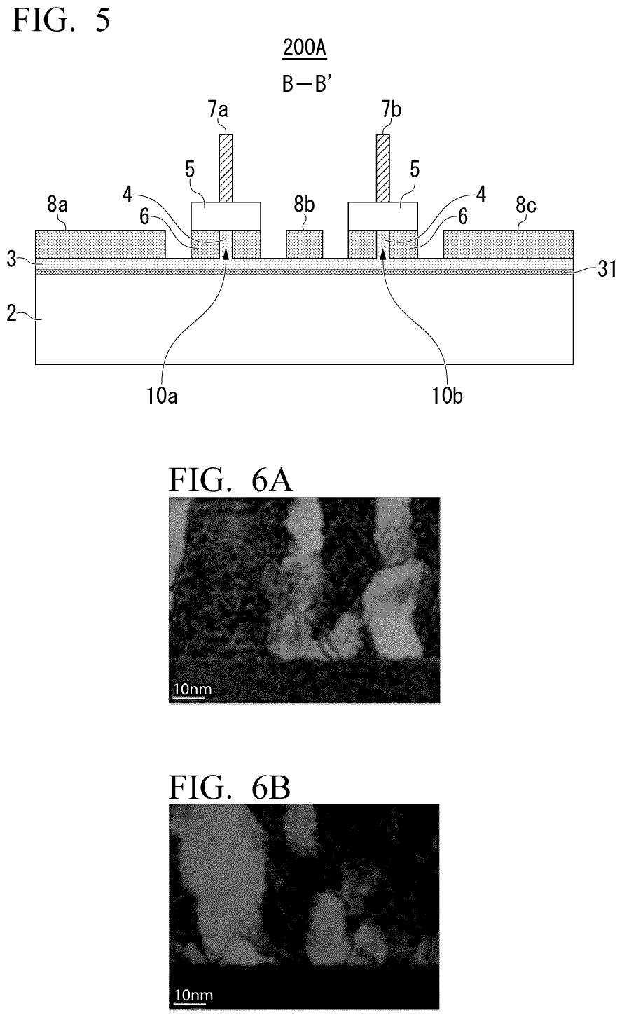

FIG. 4 is a plan view illustrating an example of an optical modulation element 200A of a Mach-Zehnder type using the substrate with a dielectric thin film 1 illustrated in FIG. 1. FIG. 5 is a cross-sectional view of the optical modulation element 200A taken along line B-B′ in FIG. 4. The cross-sectional view of the optical modulation element 200A taken along line B-B′ in FIG. 4 is the same as the cross-sectional view of the optical waveguide element 100 illustrated in FIG. 3.

In the optical modulation element 200A illustrated in FIGS. 4 and 5, the same members as those in the substrate with a dielectric thin film 1 illustrated in FIG. 1 are represented by the same reference signs, and description thereof will not be repeated.

The optical modulation element 200A illustrated in FIGS. 4 and 5 is a device that applies a voltage to a Mach-Zehnder interferometer formed using an optical waveguide 10 to modulate light propagating through the optical waveguide 10. As illustrated in FIG. 4, the optical waveguide 10 includes a first optical waveguide 10a and a second optical waveguide 10b branched from one input optical waveguide, and an output optical waveguide 10c as a coupled optical waveguide of the first optical waveguide 10a and the second optical waveguide 10b.

As illustrated in FIGS. 4 and 5, respective, that is, two first electrodes 7a and 7b are provided on the first optical waveguide 10a and the second optical waveguide 10b, respectively. Accordingly, the optical modulation element 200A has a dual-electrode structure.

The optical modulation element 200A illustrated in FIGS. 4 and 5 has ridge portions 4 formed by processing the dielectric thin film 3 in the substrate with a dielectric thin film 1 illustrated in FIG. 1 in a ridge shape (protrusion-like shape). In the optical modulation element 200A, the optical waveguide 10 is formed by the ridge portions 4. As illustrated in FIG. 5, the first electrode 7a is formed over the ridge portion 4 constituting the first optical waveguide 10a of the optical waveguide 10 via a buffer layer 5. The first electrode 7b is formed over the ridge portion 4 constituting the second optical waveguide 10b of the optical waveguide 10 via a buffer layer 5.

As illustrated in FIGS. 4 and 5, second electrodes 8a, 8b, and 8c are provided to be separated from each other via the first electrodes 7a and 7b. Each of the second electrodes 8a, 8b, and 8c is formed in contact with an upper surface of a slab portion made of the dielectric thin film 3. The slab portion made of the dielectric thin film 3 is formed by thinning a part of an upper surface of the dielectric thin film 3 in the substrate with a dielectric thin film 1 illustrated in FIG. 1 by an etching method or the like. As illustrated in FIG. 4, the first electrodes 7a and 7b and the second electrodes 8a, 8b, and 8c are connected by termination resistors 9. As illustrated in FIG. 5, a dielectric layer 6 is formed in contact with a lower surface of the buffer layer 5 and a side surface of the ridge portions 4.

Next, an operation principle of the optical modulation element 200A will be described.

As illustrated in FIG. 4, the two first electrodes 7a and 7b and the second electrodes 8a, 8b, and 8c are connected by the termination resistors 9 and are made to function as a traveling-wave electrode. The second electrodes 8a, 8b, and 8c are used as ground electrodes. Then, so-called complementary signals having the same absolute value and different positive and negative phases with no phase shift are input to the two first electrodes 7a and 7b from input sides 15a and 15b of the first electrodes 7a and 7b of the optical modulation element 200A.

The lithium niobate film forming the dielectric thin film 3 in the substrate with a dielectric thin film 1 has electro-optical effects. For this reason, an electric field applied to the first optical waveguide 10a and the second optical waveguide 10b changes refractive indexes of the first optical waveguide 10a and the second optical waveguide 10b by +Δn and −Δn, respectively. As a result, a phase difference between the first optical waveguide 10a and the second optical waveguide 10b is changed. The change in phase difference allows intensity-modulated signal light to be output from the output optical waveguide 10c as a coupled optical waveguide of the first optical waveguide 10a and the second optical waveguide 10b to an output side 12.

The optical modulation element 200A of the present embodiment includes the substrate with a dielectric thin film 1 illustrated in FIG. 1. For this reason, the optical modulation element 200A of the present embodiment has the lithium niobate film forming the dielectric thin film 3 of the substrate with a dielectric thin film 1 less susceptible to the occurrence of cracks, can be applied to a wide variety of light including visible light and infrared light, is excellent in productivity and durability, and has less optical loss.

Although the preferred embodiment of the present invention has been described above, the present invention is not limited to the above-described embodiment. Various modifications may be made without departing from the spirit of the present invention, and all such modifications are included in the present invention.

### EXAMPLES

### Example 1 to Example 8, Comparative Example 2 to Comparative Example 5

The substrate with a dielectric thin film 1 illustrated in FIG. 1 is manufactured by the following method.

A sapphire single-crystal substrate which has a diameter of four inches and the main surface 2a of which is the c-plane is prepared as the single-crystal substrate 2.

### Stress Relaxation Layer Deposition Step

In the stress relaxation layer deposition step, the stress relaxation layer 31 is epitaxially grown using the sputtering method and is deposited on the main surface 2a of the single-crystal substrate 2.

A target that has a circular shape with a diameter of eight inches and has a composition of Li/(Li+Nb)=50% is used.

The target is produced using the following method. A raw material made of a sintered body containing Li₂CO₃ and Nb₂O₅ having purity equal to or greater than 3N as main raw materials is prepared. Next, the raw material is pulverized and blended using a ball mill with a ball made of ZrO₂, and a target powder material is obtained. The obtained target powder material is sintered, and the target is obtained.

The deposition of the stress relaxation layer 31 is performed while disposing the target obtained in this manner coaxially with the single-crystal substrate 2 such that a distance from the main surface 2a of the single-crystal substrate 2 is 110 mm.

The deposition of the stress relaxation layer 31 is performed under conditions that mixture gas of Ar and O₂ is used as sputter gas, the ratio of O₂ in the sputter gas is set to 45% to 65%, the gas pressure is set to 0.08 Pa to 0.4 Pa, the temperature of the single-crystal substrate 2 is set to 550 to 700° C., and power of 1500 to 2000 W is applied such that the deposition rate is 500 nm/h to 600 nm/h. A deposition time is changed, so that the film thickness of the stress relaxation layer 31 is a predetermined film thickness.

The stress relaxation layer 31 is deposited in a so-called single step without changing the deposition conditions in the middle.

### Dielectric Thin Film Deposition Step

In the dielectric thin film deposition step, the dielectric thin film 3 is epitaxially grown using the sputtering method and is deposited on the stress relaxation layer 31.

A target that has a circular shape with a diameter of eight inches and has a composition of Li/(Li+Nb)=50% is used.

The target is produced using the following method. A raw material made of a sintered body containing Li₂CO₃ and Nb₂O₅ having purity equal to or greater than 3N as main raw materials is prepared. Next, the raw material is pulverized and blended using a ball mill with a ball made of ZrO₂, and a target powder material is obtained. The obtained target powder material is sintered, and the target is obtained.

The deposition of the dielectric thin film 3 is performed while disposing the target obtained in this manner coaxially with the single-crystal substrate 2 such that a distance from the stress relaxation layer 31 formed on the main surface 2a of the single-crystal substrate 2 is 110 mm.

The deposition of the dielectric thin film 3 is successively performed after the stress relaxation layer 31 is deposited by the sputtering method.

The deposition of the dielectric thin film 3 is performed by the sputtering method similarly to the deposition method of the stress relaxation layer 31, except that the conditions of the ratio of O₂ in the sputter gas and the gas pressure are changed.

Specifically, the deposition of the dielectric thin film 3 is performed by decreasing the ratio of O₂ in the sputter gas and increasing the gas pressure during sputtering after the stress relaxation layer 31 is deposited. The deposition time is changed, so that the film thickness of the dielectric thin film 3 is a predetermined film thickness.

The deposition of the dielectric thin film 3 is performed in a so-called single step without changing the deposition conditions in the middle.

With the above steps, the substrate with a dielectric thin films 1 of Example 1 to Example 8 and Comparative Example 2 to Comparative Example 5 are obtained.

### Comparative Example 1

A substrate with a dielectric thin film is manufactured similarly to Example 5, except that the disposition of the dielectric thin film 3 is performed on a main surface 2a of a single-crystal substrate 2 without the disposition of a stress relaxation layer 31.

### Example 9, Example 10, Comparative Example 6 to Comparative Example 8

Substrate with a dielectric thin films 1 of Example 9, Example 10, and Comparative Example 6 to Comparative Example 8 are obtained similarly to Example 5, except that the deposition time of the stress relaxation layer 31 in the stress relaxation layer deposition step and the deposition time of the dielectric thin film 3 in the dielectric thin film deposition step are changed.

For the substrate with a dielectric thin films of Example 1 to Example 10 and Comparative Example 1 to Comparative Example 8 obtained in this manner, “presence or absence of stress relaxation layer 31” is examined by the following method, and it is confirmed that the stress relaxation layer 31 and the dielectric thin film 3 (in a case where there is no stress relaxation layer 31, the dielectric thin film 3) are the epitaxial films, by first confirming a peak intensity at an orientation position by 2θ-θ X-ray diffraction and secondly confirming a pole in pole measurement with the above-described method.

### Presence or Absence of Stress Relaxation Layer 31

A cross section of the substrate with a dielectric thin film 1 is observed at a magnification of 400,000 with a scanning transmission electron microscope (STEM) (manufactured by FEI Corporation). In an obtained image, it is confirmed whether or not the twin crystal structure of LiNbO₃ and the LiNb₃O₈ phase 3c exist within a range of a length equal to or greater than 200 nm on the interface between the single-crystal substrate 2 and the stress relaxation layer 31, respectively.

For the substrate with a dielectric thin film of Example 1 to Example 10 and Comparative Example 1 to Comparative Example 8, it is examined whether or not the stress relaxation layer 31 and the dielectric thin film 3 (in a case where there is no stress relaxation layer 31, the dielectric thin film 3) have the twin crystal structure of LiNbO₃, with the following method. As a result, it is confirmed that both the stress relaxation layer 31 and the dielectric thin film 3 (in a case where there is no stress relaxation layer 31, the dielectric thin film 3) in the substrate with a dielectric thin films of Example 1 to Example 10 and Comparative Example 1 to Comparative Example 8 have the twin crystal structure of LiNbO₃.

### Confirmation Method for Twin Crystal Structure of LiNbO₃

A cross section obtained by cutting the substrate with a dielectric thin film in a thickness direction is observed using a transmission electron microscope (TEM) (manufactured by FEI Corporation), and a dark-field (DF) image is obtained. In this case, input conditions of beams are adjusted such that an image of one of the first crystal 3a and the second crystal 3b included in the twin crystal structure of LiNbO₃ forming the stress relaxation layer 31 and the dielectric thin film 3 (in a case where there is no stress relaxation layer 31, the dielectric thin film 3) is in a high contrast (bright) state.

In the dark-field image obtained by adjusting the input conditions of beams as described above, in a case where the stress relaxation layer 31 and the dielectric thin film 3 (in a case where there is no stress relaxation layer 31, the dielectric thin film 3) have the twin crystal structure of LiNbO₃, an image of one of the first crystal 3a and the second crystal 3b is in a high contrast (bright) state and an image of the other crystal is in a low contrast (dark) state, so that the first crystal 3a and the second crystal 3b can be clearly distinguished. With this, it is confirmed that the stress relaxation layer 31 and the dielectric thin film 3 (in a case where there is no stress relaxation layer 31, the dielectric thin film 3) have the twin crystal structure of LiNbO₃.

For the substrate with a dielectric thin films of Example 1 to Example 10 and Comparative Example 1 to Comparative Example 8 obtained in this manner, “maximum domain width of stress relaxation layer 31”, “maximum domain width of dielectric thin film 3”, “film thickness of stress relaxation layer 31”, “film thickness of dielectric thin film 3”, “percentage of film thickness of stress relaxation layer 31 to film thickness of dielectric thin film 3”, and “ratio between first diffraction intensity corresponding to first crystal 3a and second diffraction intensity corresponding to second crystal 3b” are examined by the following methods. Results are illustrated in Table 1 and Table 2.

The types of the single-crystal substrates 2 used in the substrate with a dielectric thin films of Example 1 to Example 10 and Comparative Example 1 to Comparative Example 8 are illustrated in Table 1 and Table 2.

Example 5 is described in both Table 1 and Table 2 for comparison.

TABLE 1

| | | | | | | | Ratio between | |
|---|---|---|---|---|---|---|---|---|
| | | | | | | | First | |
| | | | | | | | Diffraction | |
| | | Percentage | | | | | Intensity | |
| | | (%) of | | | | | corresponding | |
| | | Film | | | | | to First | |
| | | Thickness | | | | | Crystal and | |
| | | of Stress | | | | | Second | |
| | | Relaxation | | | | | Diffraction | |
| | Presence | Layer to | Domain | | Film | | Intensity | |
| | or | Film | Width | Domain | Thickness | Film | corresponding | |
| | Absence | Thickness | (nm) of | Width | (nm) of | Thickness | to Second | |
| | of Stress | of | Stress | (nm) of | Stress | (nm) of | Crystal of | |
| | Relaxation | Dielectric | Relaxation | Dielectric | Relaxation | Dielectric | Dielectric | Single-Crystal |
| | Layer | Thin Film | Layer | Thin Film | Layer | Thin Film | Thin Film | Substrate |
| Comparative | Absent | 0 | — | 158 | 0 | 1500 | 0.92 | Sapphire |
| Example 1 | | | | | | | | |
| Comparative | Present | 1 | 113 | 156 | 15 | 1500 | 1.00 | Sapphire |
| Example 2 | | | | | | | | |
| Comparative | Present | 3 | 92 | 154 | 45 | 1500 | 0.92 | Sapphire |
| Example 3 | | | | | | | | |
| Example 1 | Present | 5 | 71 | 148 | 75 | 1500 | 1.04 | Sapphire |
| Example 2 | Present | 8 | 65 | 141 | 120 | 1500 | 1.00 | Sapphire |
| Example 3 | Present | 10 | 63 | 138 | 150 | 1500 | 1.08 | Sapphire |
| Example 4 | Present | 12 | 53 | 138 | 180 | 1500 | 1.00 | Sapphire |
| Example 5 | Present | 15 | 47 | 132 | 225 | 1500 | 0.92 | Sapphire |
| Example 6 | Present | 18 | 34 | 130 | 270 | 1500 | 1.04 | Sapphire |
| Example 7 | Present | 22 | 22 | 131 | 330 | 1500 | 1.08 | Sapphire |
| Example 8 | Present | 25 | 20 | 128 | 375 | 1500 | 1.00 | Sapphire |
| Comparative | Present | 30 | 18 | 127 | 450 | 1500 | 0.96 | Sapphire |
| Example 4 | | | | | | | | |
| Comparative | Present | 40 | 17 | 127 | 600 | 1500 | 1.00 | Sapphire |
| Example 5 | | | | | | | | |

TABLE 2

| | | | | | | | Ratio between | |
|---|---|---|---|---|---|---|---|---|
| | | | | | | | First | |
| | | Percentage | | | | | Diffraction | |
| | | (%) of | | | | | Intensity | |
| | | Film | | | | | corresponding | |
| | | Thickness | | | | | to First | |
| | | of Stress | | | | | Crystal and | |
| | | Relaxation | | | | | Second | |
| | | Layer to | | | | | Diffraction | |
| | Presence | Film | Domain | | Film | | Intensity | |
| | or | Thickness | Width | Domain | Thickness | Film | corresponding | |
| | Absence | of | (nm) of | Width | (nm) of | Thickness | to Second | |
| | of Stress | Dielectric | Stress | (nm) of | Stress | (nm) of | Crystal of | |
| | Relaxation | Film | Relaxation | Dielectric | Relaxation | Dielectric | Dielectric | Single-Crystal |
| | Layer | Thickness | Layer | Thin Film | Layer | Thin Film | Thin Film | Substrate |
| Comparative | Present | 15 | 47 | 124 | 45 | 300 | 1.04 | Sapphire |
| Example 6 | | | | | | | | |
| Example 9 | Present | 15 | 48 | 128 | 75 | 500 | 1.04 | Sapphire |
| Example 5 | Present | 15 | 47 | 132 | 225 | 1500 | 0.92 | Sapphire |
| Example 10 | Present | 15 | 50 | 132 | 300 | 2000 | 1.00 | Sapphire |
| Comparative | Present | 15 | 47 | 135 | 330 | 2200 | 1.00 | Sapphire |
| Example 7 | | | | | | | | |
| Comparative | Present | 15 | 48 | 134 | 375 | 2500 | 1.08 | Sapphire |
| Example 8 | | | | | | | | |

### Maximum Domain Width of Stress Relaxation Layer r 31

The cross section of the substrate with a dielectric thin film 1 is observed at a magnification of 400,000 with a scanning transmission electron microscope (STEM) (manufactured by FEI Corporation). In an obtained image, the maximum domain width in the direction perpendicular to the thickness direction is measured for each first crystal 3a, each second crystal 3b, and the LiNb₃O₈ phase 3c that exist within the range of the length of 200 nm to 800 nm on the interface between the single-crystal substrate 2 and the stress relaxation layer 31 and are included in the twin crystal structure of LiNbO₃. A maximum dimension among the maximum domain widths of a plurality of first crystals 3a, a plurality of second crystals 3b, and a plurality of LiNb₃O₈ phases 3c that exist within the range of the length of 200 nm to 800 nm is extracted from the results and defined as “maximum domain width of stress relaxation layer 31”.

### Maximum Domain Width of Dielectric Thin Film 3

The cross section of the substrate with a dielectric thin film 1 is observed at a magnification of 400,000 with a scanning transmission electron microscope (STEM) (manufactured by FEI Corporation). In an obtained image, the maximum domain width in the direction perpendicular to the thickness direction is measured for each first crystal 3a and each second crystal 3b that exist within the range of the length of 200 nm to 800 nm on the interface between the single-crystal substrate 2 and the stress relaxation layer 31 and are included in the twin crystal structure of LiNbO₃. A maximum dimension among the maximum domain widths of a plurality of first crystals 3a and a plurality of second crystals 3b that exist within the range of the length of 200 nm to 800 nm is extracted from the results and is defined as “maximum domain width of dielectric thin film 3”.

Film Thickness of Stress relaxation layer 31, Film Thickness of Dielectric Thin Film 3, and Percentage of Film Thickness of Stress relaxation layer 31 to Film Thickness of Dielectric Thin Film 3

A film thickness of the stress relaxation layer 31 and a film thickness of the dielectric thin film 3 in the substrate with a dielectric thin film 1 are obtained by performing high resolution analysis using a scanning transmission electron microscope (STEM) (manufactured by FEI Corporation) to measure film thicknesses of three locations in a visual field and calculate an average value of the film thicknesses. A percentage of the film thickness of the stress relaxation layer 31 to the film thickness of the dielectric thin film 3 is calculated using the following equation based on the film thickness of the stress relaxation layer 31 and the film thickness of the dielectric thin film 3 calculated using the above-described method.
percentage of film thickness of stress relaxation layer 31=(stress relaxation layer 31/dielectric thin film 3)×100(%)
   Ratio between First Diffraction Intensity corresponding to First Crystal 3a and Second Diffraction Intensity corresponding to Second Crystal 3b of Dielectric Thin Film 3

For the dielectric thin film 3 of the substrate with a dielectric thin film 1, pole measurement by an X-ray diffraction method is performed using an X-ray diffractometer (Rigaku Corporation), so that the first diffraction intensity corresponding to the first crystal 3a and the second diffraction intensity corresponding to the second crystal 3b of the dielectric thin film 3 are measured. The ratio of the first diffraction intensity and the second diffraction intensity is calculated using the results.

For the substrate with a dielectric thin films of Example 1 to Example 18 and Comparative Example 1, “stress of dielectric thin film”, “presence or absence of crack in dielectric thin film 3”, “presence or absence of crack caused by annealing”, and “optical loss of dielectric thin film” are examined. The results are illustrated in Table 3 and Table 4.

TABLE 3

| | | | Presence or Absence of | |
|---|---|---|---|---|
| | | Presence or Absence of | Crack in Dielectric | |
| | Film Stress | Crack in Dielectric | Thin Film caused by | Propagation Loss |
| | (MPa) | Thin Film | 600° C. Annealing | (dB/cm) |
| Comparative Example | 18 | Absent | Present | 0.4 |
| 1 | | | | |
| Comparative Example | −7 | Absent | Present | 0.4 |
| 2 | | | | |
| Comparative Example | −45 | Absent | Present | 0.4 |
| 3 | | | | |
| Example 1 | −91 | Absent | Absent | 0.5 |
| Example 2 | −112 | Absent | Absent | 0.5 |
| Example 3 | −140 | Absent | Absent | 0.5 |
| Example 4 | −151 | Absent | Absent | 0.5 |
| Example 5 | −174 | Absent | Absent | 0.5 |
| Example 6 | −189 | Absent | Absent | 0.5 |
| Example 7 | −215 | Absent | Absent | 0.5 |
| Example 8 | −231 | Absent | Absent | 0.7 |
| Comparative Example | −253 | Absent | Absent | 1.2 |
| 4 | | | | |
| Comparative Example | −253 | Absent | Absent | 1.5 |
| 5 | | | | |

TABLE 4

| | | | Presence or Absence of | |
|---|---|---|---|---|
| | | Presence or Absence of | Crack in Dielectric | |
| | Film Stress | Crack in Dielectric | Thin Film caused by | Propagation Loss |
| | (MPa) | Thin Film | 600° C. Annealing | (dB/cm) |
| Comparative Example | −729 | Absent | Absent | 2.3 |
| 6 | | | | |
| Example 9 | −468 | Absent | Absent | 0.9 |
| Example 5 | −174 | Absent | Absent | 0.5 |
| Example 10 | −118 | Absent | Absent | 0.5 |
| Comparative Example | −92 | Absent | Present | 0.5 |
| 7 | | | | |
| Comparative Example | −49 | Absent | Present | 0.5 |
| 8 | | | | |

### Stress of Dielectric Thin Film

An amount of curvature of the dielectric thin film 3 in the substrate with a dielectric thin film 1 is measured using a needle-contact type step meter (manufactured by KLA-Tenchore Corporation), and the stress of the dielectric thin film is calculated by Stoney's equation.

A case where an obtained numerical value of the stress of the dielectric thin film is “plus (+)” is evaluated as tensile stress. A case where the numerical value of the stress of the dielectric thin film is “minus (−)” is evaluated as compressive stress.

### Presence or Absence of Crack in Dielectric Thin Film 3

The substrate with a dielectric thin film is observed using an optical microscope (manufactured by Olympus Corporation) in which a diameter of visual field is about 0.5 mm when a magnification of an objective lens is 20× and a diameter of visual field is about 0.1 mm when a magnification of an objective lens is 100×, and the presence or absence of a crack in the dielectric thin film 3 is examined.

In a case where no crack is confirmed, it is evaluated that a crack is “absent”. In a case where any one crack is confirmed, it is evaluated that a crack is “present”.

### Presence or Absence of Crack in Dielectric Thin Film 3 Caused by Annealing

Annealing for one hour at 600° C. is performed on the substrate with a dielectric thin film 1 in an oxygen atmosphere at a pressure of one atmosphere.

Thereafter, similarly to “presence or absence of crack in dielectric thin film 3” described above, the presence or absence of a crack in the dielectric thin film 3 is examined and evaluated.

### Optical Loss of Dielectric Thin Film

Infrared light of 1550 nm is made to propagate through the dielectric thin film of the substrate with a dielectric thin film, and propagation loss in the dielectric thin film is measured using a prism coupler (manufactured by Metricon Corporation).

A case where the propagation loss is less than 1 dB/cm is evaluated as pass. A case where the propagation loss is equal to or greater than 1 dB/cm is evaluated as failure.

As illustrated in Table 3 and Table 4, in all of the substrate with a dielectric thin films of Example 1 to Example 10, the numerical value of “stress of dielectric thin film” is “minus (−)” and indicates compressive stress, and a crack in the dielectric thin film 3 and a crack caused by annealing are “absent”. In all of the substrate with a dielectric thin films of Example 1 to Example 10, the propagation loss in the dielectric thin film is less than 1 dB/cm, and the optical loss of the dielectric thin film is small.

In contrast, as illustrated in Table 3 and Table 4, in the substrate with a dielectric thin film of Comparative Example 1 having no stress relaxation layer 31, the numerical value of “stress of dielectric thin film” is “plus (+)” and indicates tensile stress, and a crack in the dielectric thin film 3 and a crack caused by annealing are “present”.

From this, it can be confirmed that the substrate with a dielectric thin film in which the single-crystal substrate 2 and the dielectric thin film 3 are in contact with each other via the stress relaxation layer 31 is provided, so that the dielectric thin film 3 is less susceptible to the occurrence of cracks.

As illustrated in Table 3, in Comparative Example 2 and Comparative Example 3 where the percentage of the film thickness of the stress relaxation layer 31 to the film thickness of the dielectric thin film 3 is less than 5%, a crack in the dielectric thin film 3 is “absent”, but a crack caused by annealing is “present”.

As illustrated in Table 4, in Comparative Example 7 and Comparative Example 8 where the film thickness of the stress relaxation layer 31 is greater than 2 μm, a crack in the dielectric thin film 3 is “absent”, but a crack caused by annealing is “present”.

As illustrated in Table 3, in Comparative Example 4 and Comparative Example 5 where the percentage of the film thickness of the stress relaxation layer 31 to the film thickness of the dielectric thin film 3 is greater than 25%, a crack in the dielectric thin film 3 and a crack caused by annealing are “absent”. However, in both Comparative Example 4 and Comparative Example 5, the propagation loss in the dielectric thin film is greater than 1 dB/cm, and the optical loss of the dielectric thin film is large.

As illustrated in Table 4, in Comparative Example 6 where the film thickness of the stress relaxation layer 31 is less than 0.5 μm, a crack in the dielectric thin film 3 and a crack caused by annealing are “absent”. However, in Comparative Example 6, the propagation loss in the dielectric thin film is greater than 1 dB/cm, and the optical loss of the dielectric thin film is large.

Mapping Analysis of Substrate with a Dielectric Thin Film

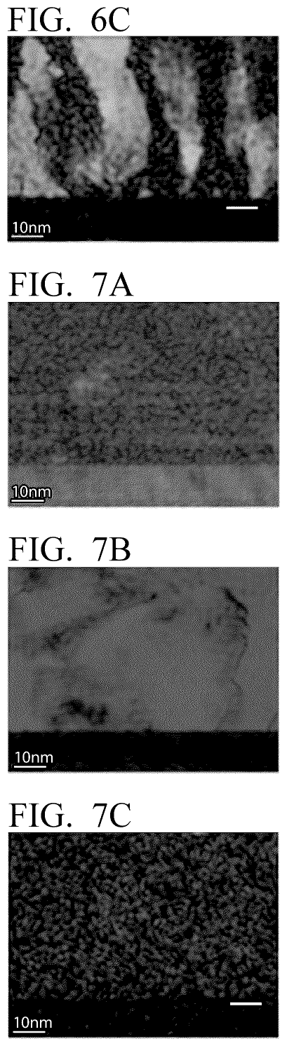

For the substrate with a dielectric thin films of Example 5 and Comparative Example 1, mapping analysis of the interface between the single-crystal substrate 2 and the stress relaxation layer 31 or the dielectric thin film 3 in the cross section of the substrate with a dielectric thin film is performed using a scanning transmission electron microscope (STEM) (manufactured by FEI Corporation). The results are illustrated in FIGS. 6A to 6C and 7A to 7C.

FIGS. 6A to 6C are photographs illustrating an image obtained by mapping analysis of the interface between the single-crystal substrate 2 and the stress relaxation layer 31 of Example 5. In FIGS. 6A to 6C, a region made of a single phase in a lower portion is the single-crystal substrate 2. FIGS. 6A and 6B are photographs of the first crystal 3a and the second crystal 3b forming the twin crystal structure of LiNbO₃ included in the stress relaxation layer 31. FIG. 6C is a photograph of the LiNb₃O₈ phase 3c included in the stress relaxation layer 31.

FIGS. 7A to 7C are photographs illustrating an image obtained by mapping analysis of an interface between a single-crystal substrate 2 and a dielectric thin film 3 of Comparative Example 1. In FIGS. 7A to 7C, a region made of a single phase in a lower portion is the single-crystal substrate 2. FIGS. 7A and 7B are photographs of the first crystal 3a and the second crystal 3b forming the twin crystal structure of LiNbO₃ included in the dielectric thin film 3. FIG. 7C is a photograph of the LiNb₃O₈ phase 3c included in the dielectric thin film 3.

As illustrated in FIGS. 6A to 6C, it can be confirmed that the stress relaxation layer 31 of Example 5 has a very small maximum domain width compared to the dielectric thin film 3 of Comparative Example 1 illustrated in FIGS. 7A to 7C.

As illustrated in FIG. 6C, the LiNb₃O₈ phase 3c included in the stress relaxation layer 31 of Example 5 is grown substantially vertically with respect to the main surface of the single-crystal substrate 2, and coexists in the stress relaxation layer 31 with the first crystal 3a and the second crystal 3b forming the twin crystal structure of LiNbO₃ grown substantially vertically with respect to the main surface of the single-crystal substrate 2 illustrated in FIGS. 6A and 6B.

In contrast, as illustrated in FIG. 7C, the LiNb₃O₈ phase 3c included in the dielectric thin film 3 of Comparative Example 1 is not grown from the single-crystal substrate 2.

Accordingly, the LiNb₃O₈ phase 3c included in the stress relaxation layer 31 of Example 5 can be easily distinguished from the LiNb₃O₈ phase 3c included in the dielectric thin film 3 of Comparative Example 1.

### EXPLANATION OF REFERENCES

1 Substrate with a dielectric thin film
2 Single-crystal substrate
2a Main surface
3 Dielectric thin film
3a First crystal
3b Second crystal
3c LiNb₃O₈ phase
4 Ridge portion
5 Buffer layer
6 Dielectric layer
7a, 7b First electrode
8a, 8b, 8c Second electrode
9 Termination resistor
10 Optical waveguide
10a First optical waveguide
10b Second optical waveguide
10c Output optical waveguide
12 Output side
15a, 15b Input side
31 Stress relaxation layer
100 Optical waveguide element
200A Optical modulation element

What is claimed is:

1. A substrate with a dielectric thin film comprising:
a single-crystal substrate;
a stress relaxation layer formed in contact with a main surface of the single-crystal substrate; and
a dielectric thin film formed in contact with the stress relaxation layer,
wherein the stress relaxation layer is made of a c-axis-oriented epitaxial film, and includes: a twin crystal structure of LiNbO₃ including a first crystal and a second crystal that is rotated 180° about a c-axis with respect to the first crystal; and a LiNb₃O₈ phase,
the dielectric thin film is made of a lithium niobate film which is a c-axis-oriented epitaxial film, has the twin crystal structure of LiNbO₃, has a film thickness of 0.5 μm to 2 μm, and has a maximum domain width greater than a maximum domain width of the stress relaxation layer, and
a percentage of a film thickness of the stress relaxation layer to the film thickness of the dielectric thin film is 5% to 25%.

2. The substrate with a dielectric thin film according to claim 1,
wherein the maximum domain width of the stress relaxation layer is 20 nm to 70 nm.

3. The substrate with a dielectric thin film according to claim 1,
wherein the single-crystal substrate is a sapphire single-crystal substrate the main surface of which is a c-plane.

4. The substrate with a dielectric thin film according to claim 1,
wherein the twin crystal structure of the dielectric thin film has a ratio between a first diffraction intensity corresponding to the first crystal and a second diffraction intensity corresponding to the second crystal equal to or greater than 0.5 and equal to or less than 2.0 in pole measurement by an X-ray diffraction method.

5. An optical waveguide element comprising:
the substrate with a dielectric thin film according to claim 1.

6. An optical modulation element comprising:
the substrate with a dielectric thin film according to claim 1.
